(19) United States
(12) Patent Application Publication
(10) Pub. No.: US 2013/0335093 A1
(43) Pub. Date: Dec. 19, 2013

(54) METHOD FOR MEASURING THE LIGHT PROPERTIES OF LIGHT-EMITTING DIODES

(71) Applicant: Diehl Aerospace GmbH, Uberlingen (DE)

(72) Inventors: Steffen BACHMAIER, Nurnberg (DE); Nicolaus KANGARAKIS, Nurnberg (DE)

(73) Assignee: Diehl Aerospace GmbH, Uberlingen (DE)

(21) Appl. No.: 13/901,030

(22) Filed: May 23, 2013

(30) Foreign Application Priority Data
Jun. 13, 2012 (DE) 102012011738.8

(51) Int. Cl. G01R 31/44

(52) U.S. Cl. CPC G01R 31/44
USPC 324/414

(57) ABSTRACT

The invention relates to a method for measuring the light properties of light-emitting diodes (LEDs) in an arrangement of a plurality of channels connected in parallel, each having at least one LED per channel and a driver for driving the channels by means of pulse width modulation (PWM), in such a way that at least one pulse of predetermined width can be generated for each channel within a PWM period, wherein the LED of a selected channel is measured during a measurement interval, the measurement interval overlapping a pulse, lying within the PWM period, of a selected channel.

### BACKGROUND OF THE INVENTION

The invention relates to a method for measuring the light properties of light-emitting diodes (LEDs) in an arrangement of a plurality of channels (B, G, R, W) connected in parallel, each having at least one LED per channel (B, G, R, W) and a driver for driving the channels (B, G, R, W) by means of pulse width modulation (PWM), in such a way that at least one pulse (p1, p2, p3, p4) of predetermined width can be generated for each channel (B, G, R, W) within a PWM period, wherein the LED of a selected channel (B, G, R, W) is measured during a measurement interval (M), the measurement interval (M) overlapping a pulse (p1, p2, p3, p4), lying within the PWM period, of a selected channel (B, G, R, W).

### DISCUSSION OF THE PRIOR ART

According to the prior art, an arrangement of a plurality of channels connected in parallel, each having at least one LED per channel and a driver for driving the channels by means of pulse width modulation, is generally known. Reference is made, for example, to WO 2012/000695 A1.

According to the prior art, in this context, arrangements having four channels are known in particular, in which blue LEDs are driven with a first channel, green LEDs are driven with a second channel, red LEDs are driven with a third channel and white LEDs are driven with a fourth channel. According to the pulse width modulation of the individual channels, light with a predetermined colour and brightness can therefore be generated.

Light-emitting diodes age in the course of time. As a result of this, their colour and/or their brightness can change. These changes can be compensated for by altering the pulse width modulation of the respective channel. A prerequisite for this is that the brightness and/or the colour of the light-emitting diodes of each channel is measured in mixed operation.

During mixed operation, pulses, which may overlap in time, are applied in each channel over a pulse width modulation period (PWM period). In order to measure the light-emitting diodes of a channel, according to the prior art it is known to switch off the other channels. When the other channels are switched off, a light flash is produced, which is perceived as disruptive by the user. Light mixing is not possible while the other channels are switched off.

In order to overcome this disadvantage, according to the prior art it is also known for those pulses of the other channels which overlap with the measurement interval only to be switched off for the duration of the measurement interval. The colour and the brightness of the mixed light change in this case. This is also perceived as disruptive by the user.

### SUMMARY OF THE INVENTION

It is an object of the invention to provide a method for measuring the light properties of light-emitting diodes in an arrangement of a plurality of channels connected in parallel, each having at least one LED per channel and a driver for driving the channels by means of pulse width modulation, which method is imperceptible or scarcely perceptible for the user by a change in the mixed colour. According to another aim of the invention, the method should be as simple and as economical as possible to carry out.

This object is achieved by the features of Patent claim 1. Expedient configurations of the invention may be found from the features of Patent claims 2 to 5.

According to the invention, it is proposed that the measurement interval be located in a section of the PWM period in which, besides in the selected channel, a further pulse is also generated in a further channel, an integral of the further pulse with respect to time having a predetermined value,

and that the further pulse be shifted in time, while preserving the predetermined value within the PWM period, in such a way that it lies outside the measurement interval,

or

that, while preserving the predetermined value, the further pulse be divided into two sub-pulses, of which one lies before the measurement interval in time and one lies after the measurement interval in time.

According to the invention, the integral of the further pulse with respect to time during a PWM period therefore remains constant despite the measurement. As a result of this, the measurement by the method according to the invention is perceptible for the user neither by a change in the brightness nor by a change in the colour of the mixed light. The method according to the invention can be carried out by modifying the software controlling the PWM. It can thus be carried out simply and economically.

According to an advantageous configuration, the measurement interval is located in a section of the PWM period in which, besides in the selected channel, a further pulse is also generated in precisely one further channel. This further simplifies the implementation of the method. It is merely necessary to shift or split the further pulse in precisely one further channel.

The method according to the invention is suitable in particular for the use of arrangements for generating white mixed light. Expediently, the colour of the at least one LED of each channel differs. Advantageously, at least one blue LED is assigned to a first channel, at least one green LED is assigned to a second channel and at least one red LED is assigned to a third channel. Furthermore, a fourth channel may be provided, to which at least one white LED is assigned. Advantageously, a plurality of the respective LEDs are assigned to each channel.

### BRIEF DESCRIPTION OF THE DRAWINGS

An exemplary embodiment of the invention will be explained in more detail below with the aid of the drawing, in which:

FIG. 1 shows the distribution of pulses of four channels as a function of time within a PWM period,

FIG. 2 shows the distribution of the pulses of the four channels within the PWM period when the first channel is being measured,

FIG. 3 shows the pulses of the four channels within the PWM period when the second channel is being measured,

FIG. 4 shows the pulses of the four channels within the PWM period when the third channel is being measured, and

FIG. 5 shows the pulses of the four channels within the PWM period when the fourth channel is being measured.

### DETAILED DESCRIPTION OF THE INVENTION

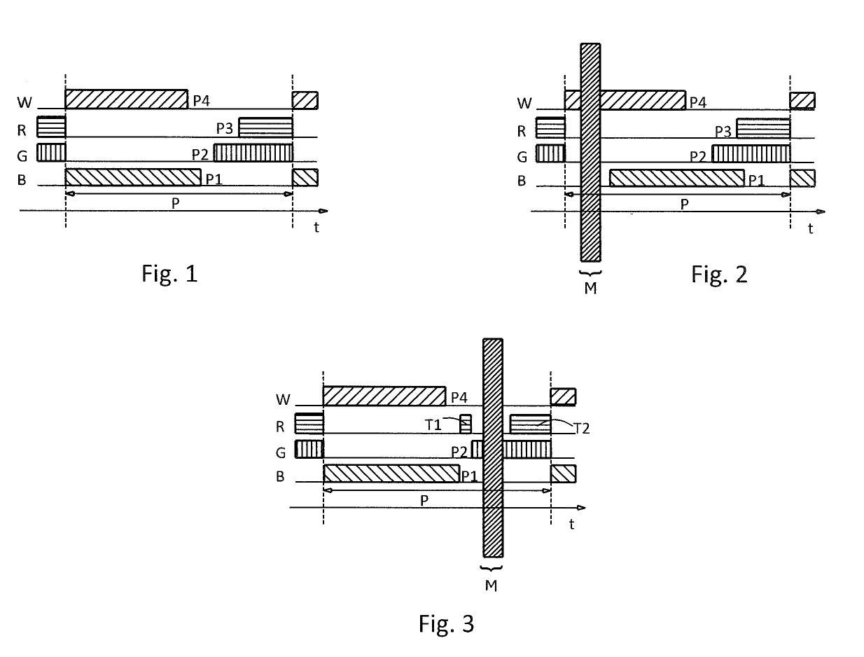

In FIGS. 1 to 5, a first pulse p1 of a first channel B, a second pulse p2 of a second channel G, a third pulse p3 of a third channel R and a fourth pulse p4 of a fourth channel W are respectively plotted as a function of time t. The pulses p1 to p4 are electrical pulses having a predetermined constant voltage. The broken lines denote the start and end of a PWM period P. At least one blue LED is assigned to the first channel B, at least one green LED is assigned to the second channel G, at least one red LED is assigned to the third channel R and at least one white LED is assigned to the fourth channel W. As can be seen from FIG. 1, with respect to time t during the PWM period P, the light-emitting diodes of the channels B, G, R, W are operated with different pulse widths and/or switch-on and switch-off times. A mixed light of predetermined colour and brightness is therefore produced.

In FIGS. 2 to 5, the vertical bar denotes a measurement interval M within the PWM period P. The measurement interval M is much shorter than the PWM period P. It is advantageously less than ⅛, particularly preferably less than 1/10, of the PWM period P.

In order to measure the light properties of the white light-emitting diode assigned to the fourth channel W, the measurement interval M is placed in such a way that it overlaps the fourth pulse p4 in the fourth channel W. During normal operation, which is shown in FIG. 1, the measurement interval M shown in FIG. 2 would simultaneously overlap the first pulse p1 in the first channel B. According to the invention, the first pulse p1 in the first channel B is now shifted in time in such a way that it no longer overlaps with the measurement interval M. At the same time, however, the pulse width of the first pulse p1 is preserved. That is to say, the integral of the first pulse p1 with respect to time t remains constant during the PWM period P. This is shown in FIG. 2. A similar method may be used for measuring the brightness of the blue LED assigned to the first channel B. That is shown in FIG. 5.

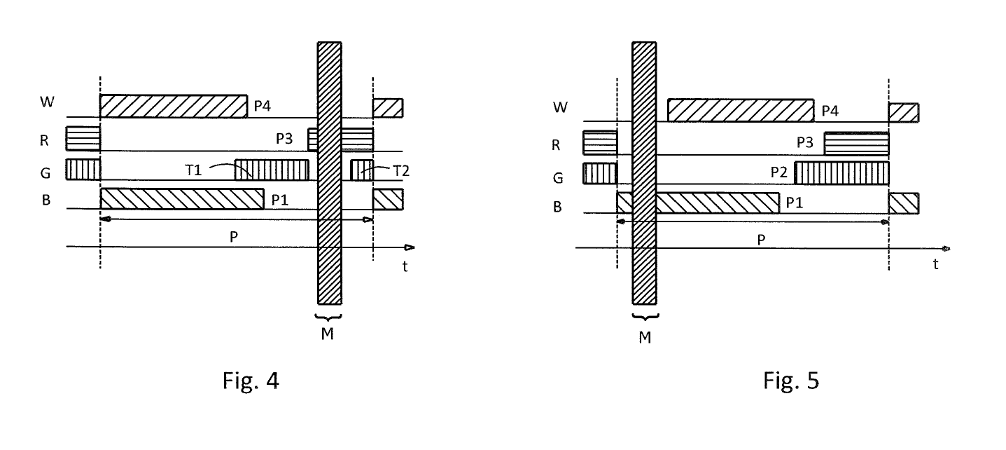

As an alternative to this, pulses overlapping the measurement interval M may also be split while preserving their pulse width. During measurement of the green light-emitting diode assigned to the second channel G, the measurement interval M would overlap with the third pulse p3 in the third channel R. According to the invention, the third pulse p3 in the third channel R is split into a first sub-pulse T1 and a second sub-pulse T2. The first sub-pulse T1 is shifted in time to before the measurement interval M. The second sub-pulse T2 lies after the measurement interval M in time. The pulse width resulting from the first sub-pulse T1 and the second sub-pulse T2 corresponds to the original pulse width during regular operation of the third channel (see FIG. 1). A similar method is shown for the measurement of the third channel in FIG. 4. In this case, the second pulse p2 in the second channel G is split into a further first sub-pulse T1′ and a further second sub-pulse T2′.

### LIST OF REFERENCES

B first channel
G second channel
R third channel
W fourth channel
M measurement interval
T1 first sub-pulse
T2 second sub-pulse
T1′ further first sub-pulse
T2′ further second sub-pulse

What is claimed is:

1. A method for measuring the light properties of light-emitting diodes (LEDs) in an arrangement of a plurality of channels (B, G, R, W) connected in parallel, each having at least one LED per channel (B, G, R, W) and a driver for driving the channels (B, G, R, W) by means of pulse width modulation (PWM), in such a way that at least one pulse (p1, p2, p3, p4) of predetermined width can be generated for each channel (B, G, R, W) within a PWM period,
wherein the LED of a selected channel (B, G, R, W) is measured during a measurement interval (M), the measurement interval (M) overlapping a pulse (p1, p2, p3, p4), lying within the PWM period, of a selected channel (B, G, R, W),
characterized in that
the measurement interval (M) is located in a section of the PWM period in which, besides in the selected channel (B, G, R, W), a further pulse (p1, p2, p3, p4) is also generated in a further channel (B, G, R, W), an integral of the further pulse (p1, p2, p3, p4) with respect to time having a predetermined value,
and in that the further pulse (p1, p2, p3, p4) is shifted in time, while preserving the predetermined value within the PWM period, in such a way that it lies outside the measurement interval (M),
or
in that, while preserving the predetermined value, the further pulse (p1, p2, p3, p4) is divided into two sub-pulses (T1, T2, T1′, T2′), of which one lies before the measurement interval (M) in time and one lies after the measurement interval (M) in time.

2. The method according to claim 1, wherein the measurement interval (M) is located in a section of the PWM period in which, besides in the selected channel (B, G, R, W), a further pulse (p1, p2, p3, p4) is also generated in precisely one further channel (B, G, R, W).

3. The method according to claim 1, wherein the colour of the at least one LED of each channel (B, G, R, W) differs.

4. The method according to claim 1, wherein at least one blue LED is assigned to a first channel (B), at least one green LED is assigned to a second channel (G) and at least one red LED is assigned to a third channel (R).

5. The method according to claim 1, wherein at least one white LED is assigned to a fourth channel (W).
